(19) United States
(12) Patent Application Publication
(10) Pub. No.: US 2025/0012850 A1
(43) Pub. Date: Jan. 9, 2025

(54) METHOD AND MEASUREMENT APPLICATION SYSTEM CONFIGURATION SYSTEM

(71) Applicant: Rohde & Schwarz GmbH & Co. KG, München (DE)

(72) Inventors: Thomas BRAUNSTORFINGER, München (DE); Bjoern SCHMID, München (DE); Florian LANG, Gilching (DE); Sebastian ROEGLINGER, Pfaffenhofen (DE)

(21) Appl. No.: 18/348,803

(22) Filed: Jul. 7, 2023

(51) Int. Cl. G01R 31/28

(52) U.S. Cl. CPC G01R 31/2834

(57) ABSTRACT

A method for configuring a measurement application system is provided, the method comprising providing to a configuration device a system description data structure that defines, for one or more measurement application devices that are present in the measurement application system, properties, and constraints, and dependencies of properties, receiving for at least one of the properties a user input comprising a value to be set for the respective property, evaluating at least one of the constraints or dependencies based on the at least one value received via the user input, updating, if according to the evaluation the at least one of the constraints or dependencies are fulfilled, at the configuration device the system description data structure according to the at least one value received via the user input, and updating a configuration of the one or more measurement application devices according to the updated system description data structure.

### TECHNICAL FIELD

The disclosure relates to a method for configuring a measurement application system, and to a respective measurement application system configuration system.

### BACKGROUND

Although applicable to any type of measurement application system, the present disclosure will mainly be described in conjunction with measurement systems for performing measurements in electronic devices.

Modern measurement application systems may comprise a plurality of different measurement application devices that may be used to perform specific measurement tasks with respective devices under test or DUTs. Such measurement application devices may comprise signal generation and signal measurement devices that may be coupled to one or multiple DUTs. Further, measurement application devices may be communicatively coupled to each other e.g., via a data network.

Configuring multiple measurement application devices in such a measurement application system is a complex task.

Accordingly, there is a need for simplifying configuration of measurement application devices in a measurement application system.

### SUMMARY

The above stated problem is solved by the features of the independent claims. It is understood, that independent claims of a claim category may be formed in analogy to the dependent claims of another claim category.

Accordingly, it is provided:

A method for configuring a measurement application system, the method comprising providing to a configuration device a system description data structure that defines, for one or more measurement application devices that are present in the measurement application system, properties and at least one of constraints for at least one of the properties, and dependencies of at least one of the properties that depend on at least another one of the properties; receiving at the configuration device for at least one of the properties a user input comprising a value to be set for the respective property; evaluating at the configuration device at least one i.e. one, two, three or more, especially all, of the constraints or dependencies based on the at least one value received via the user input; updating, if according to the evaluation the at least one of the constraints or dependencies is fulfilled, at the configuration device the system description data structure according to the at least one value received via the user input; and updating, if according to the evaluation the at least one of the constraints or dependencies is fulfilled, a configuration of the one or more measurement application devices according to the updated system description data structure.

Further, it is provided:

A measurement application system configuration system comprising a source device configured to provide a system description data structure that defines, for at least one measurement application device of a measurement application system, properties and at least one of constraints for at least one of the properties, and dependencies of at least one of the properties that depends on at least another one of the properties, and comprising a configuration device configured to receive for at least one of the properties a user input comprising a value to be set for the respective property, evaluate at least one i.e. one, two, three or more, especially all, of the constraints or dependencies based on the at least one value received via the user input, update, if according to the evaluation the at least one, especially all, of the constraints or dependencies is fulfilled, the system description data structure according to the at least one value received via the user input, and transmit, if according to the evaluation the at least one, especially all, of the constraints or dependencies is fulfilled, an updated configuration to the one or more measurement application devices according to the updated system description data structure.

The present disclosure is based on the finding that configuring complex measurement application systems with a plurality of measurement application devices is a cumbersome task. Further, a user may configure single measurement application devices in a way that is not compatible with other measurement application devices in the measurement application system. Keeping track of all dependencies between the measurement application devices becomes increasingly difficult for a user with increasing number of measurement application devices.

In addition, in complex measurement application systems with a plurality of different measurement application devices, configuring the single measurement application devices remotely results in an increased data communication between the remote configuration device and the single measurement application devices e.g., for transmitting the single configuration commands to all the measurement application devices.

The present disclosure, therefore, provides a method and a measurement application system that allows easily configuring a plurality of measurement application devices correctly in the measurement application system with only little communication effort.

A measurement application device according to the present disclosure may comprise any device that may be used in a measurement application to acquire an input signal or to generate an output signal, or to perform additional or supporting functions in a measurement application. A measurement application device may also comprise or be implemented as application or applications, also called measurement application or measurement applications, that may be executed on a computer device or in one of the other measurement application devices and that may communicate with other measurement application devices in order to perform a measurement task. A measurement application, also called measurement setup, may e.g., comprise at least one or multiple different measurement application devices for performing electric, magnetic, or electromagnetic measurements, especially on single devices under test. Such electric, magnetic, or electromagnetic measurements may be performed in a measurement laboratory or in a production facility in the respective production line. A measurement application or measurement setup may serve to qualify the single devices under test i.e., to determine the proper electrical operation of the respective devices under test.

Measurement application devices to this end may comprise at least one signal acquisition section for acquiring electric, magnetic, or electromagnetic signals to be measured from a device under test, or at least one signal generation section for generating electric, magnetic, or electromagnetic signals that may be provided to the device under test. Such a signal acquisition section may comprise, but is not limited to, a front-end for acquiring, filtering, and attenuating or amplifying electrical signals. The signal generation section may comprise, but is not limited to, respective signal generators, amplifiers, and filters.

Further, when acquiring signals, measurement application devices may comprise a signal processing section that may process the acquired signals. Processing may comprise converting the acquired signals from analog to digital signals, and any other type of digital signal processing, for example, converting signals from the time-domain into the frequency-domain.

The measurement application devices may also comprise a user interface to display the acquired signals to a user and allow a user to control the measurement application devices. Of course, a housing may be provided that comprises the elements of the measurement application device. It is understood, that further elements, like power supply circuitry, and communication interfaces may be provided.

A measurement application device may be a stand-alone device that may be operated without any further element in a measurement application to perform tests on a device under test. Of course, communication capabilities may also be provided for the measurement application device to interact with other measurement application devices.

A measurement application device may comprise, for example, a signal acquisition device e.g., an oscilloscope, especially a digital oscilloscope, a spectrum analyzer, or a vector network analyzer. Such a measurement application device may also comprise a signal generation device e.g., a signal generator, especially an arbitrary signal generator, also called arbitrary waveform generator, or a vector signal generator. Further possible measurement application devices comprise devices like calibration standards, or measurement probe tips.

Of course, at least some of the possible functions, like signal acquisition and signal generation, may be combined in a single measurement application device.

In embodiments, the measurement application device may comprise pure data acquisition devices that are capable of acquiring an input signal and of providing the acquired input signal as digital input signal to a respective data storage or application server. Such pure data acquisition devices not necessarily comprise a user interface or display. Instead, such pure data acquisition devices may be controlled remotely e.g., via a respective data interface, like a network interface or a USB interface. The same applies to pure signal generation devices that may generate an output signal without comprising any user interface or configuration input elements. Instead, such signal generation devices may be operated remotely via a data connection.

According to the present disclosure a system description data structure is provided e.g., to a configuration device. The system description data structure may be provided by the measurement application system. For example, the single measurement application devices may each provide a respective part of the system description data structure. In embodiments, a dedicated application or device may be provided in the measurement application system that created and provides the system description data structure. Such a device or application may be the source device of the measurement application system configuration system.

The configuration device serves for a user to input the configuration data for the single measurement application devices and may in embodiments comprise a computer, a tablet-PC, a smartphone, a cloud system, or the like that executes a respective application or software program. In embodiments, the application or software program may be implemented as an interactive webpage e.g., based on HTML and JavaScript, or as native applications or programs that are executed on the configuration device. The configuration device may implement a respective user facing front end that allows a user to control the configuration device and provide user input. Such a front end may be implemented as that part of the configuration device that is executed on the user's device. For example, as an HTML based user interface. In embodiments, the front end may also perform the evaluation and the updating of the system description data structure. In embodiments, a respective back end may be provided e.g., on a server serving the HTML based user interface application. Such a back end may receive the evaluated and updated system description data structure from the front end and may communicate with the measurement application devices to update the measurement application devices accordingly. Such a back end may also be part of the measurement application system.

The configuration device may be part of the measurement application system, or may be external to the measurement application system and coupled communicatively e.g., via a data network, to the measurement application system. In embodiments, the configuration device may also be provided in a measurement application device or may be distributed in multiple measurement application devices.

The system description data structure comprises single properties for at least one of the measurement application devices of the measurement application system. In addition, the system description data structure may also comprise or describe one or more constraints for one or more of the properties, and dependencies of properties on other properties. In general, the system description data structure may be interpreted as or may implement a data representation of objects that comprise the structure and content of settings of the measurement devices of the measurement application system.

The single properties refer to variables that a user may set in the respective measurement application device. Usually, such variables may be set remotely via a data communication interface in measurement application devices. In addition, in the system description data structure additional information may be provided with the single properties. Such additional information may comprise a description of the property. Such a description may be at least one of machine readable and human readable.

According to the present disclosure, user input is received e.g., at the configuration device, that comprises a value to be set for at least one of the properties. However, instead of directly providing the user input to the respective one of the measurement application devices, the user input is first evaluated.

To this end, the constraints and dependencies are provided in the system description data structure.

The constraints may each define a constraint, like a maximum and a minimum value for a property. A constraint may also comprise a standard value for a property that is used unless the user specifies another value to be used. The dependencies may each provide for one of the properties a definition of how the respective property depends on one or multiple other properties.

Such dependencies may also comprise so called axioms or equations for each property.

For example, an axiom or equation may define a calculation rule for a property based on another property. As an example, for a property “A” an axiom or equation may be provided that defines A=X*B, wherein X and B may be other properties or constant values. An axiom or equation may also define a minimum or maximum value for a property based on other properties. For example, for the property A an axiom or equation may define one of A<B, A<=B, A>B, A>=B. Other examples of axioms or equations may comprise three components, for example, C<A<B, C<=A<B, C<A<=B, C<=A<=B, C>A>B, C>=A>B, C>A>=B, and C>=A>=B. In embodiments, a formula may be provided, for example, A<B*X, A<=B*X, A>B*X, A>=B*X. It is understood, that the above axioms or equations are just exemplarily shown, and that any type of axiom or equation comprising any type of equation may be used in specific implementations. Further, it is understood, that each B, C or X in the above examples may be substituted by a fixed value instead of a property where appropriate.

A user may provide a user input regarding at least one of the properties e.g., to set a value of a respective property.

During evaluation of the at least one of the constraints, and dependencies, it is then verified that the single axioms or equations are fulfilled with the properties having the values indicated by the respective user input.

If the constraints and dependencies are fulfilled, the configuration provided by the user may be accepted as correct. In this case, the system description data structure may be updated to comprise the values provided by the user.

The system description data structure may also comprise currently set values of the single properties, even if these are not set by a user. Such currently set values may be retrieved from the single measurement application devices via a data communication interface or may be included in the system description data structure as set in a former version of the system description data structure.

A configuration of the one or more measurement application devices of the measurement application system may then be updated based on the updated system description data structure.

For example, the single measurement application devices may each receive all or part of the system description data structure and internally perform the respective configurations. In embodiments, a dedicated application or device may be provided in the measurement application system that receives the system description data structure and performs respective configurations.

With the solution provided by the present disclosure, it is possible to evaluate the full configuration of the measurement application system locally at the configuration device and prior to providing the configuration data to the single measurement application devices of the measurement application system.

If, for example, an application is used as one of multiple measurement application devices in a measurement application system, such an application or any other measurement application device may already be configured correctly even if other measurement application devices are not present to communicate their capabilities to the application. Instead, only with the system description data structure, the application may be configured correctly.

The system description data structure may be seen as a single source of truth that may be changed and verified in the configuration device, or any other adequate device. The configuration device may be a user's PC and may, therefore, comprise more computing resources than the measurement devices. By evaluating the compliance of the user provided input with the constraints and dependencies at such a device, the performance may be improved.

Further, the system description data structure may be distributed in total or at least in part to the single measurement application devices.

In some measurement systems, single configuration commands may be provided to the single measurement application devices from the configuration device when a user inputs them at the configuration device, therefore, causing a high communication data load. Instead, with the solution of the present disclosure, data communication is only performed after all configuration input is provided by the user and verified to be correct or compliant with the constraints and dependencies.

By using the system description data structure as single source of truth, a kind of stateless measurement application systems may be provided. All the required information will be provided via the request. Therefore, any number of services e.g., measurement applications (which may be an example of a measurement application device) may be provided to any number of users at the same time, without the necessity to execute a new service per use or session. For example, instances of services may be executed based on the system CPU load or memory usage e.g., by executing a respective service for each user. This allows flexible up and down scaling of measurement application instances that are executed e.g., in a cloud or server.

Further, programming language code may be generated from the system description data structure for any programming language. The system description data structure comprises the full data model as configured for a measurement application, and is agnostic of any specific programming language. Therefore, based on this data model, code in different programming languages may be generated that may then be executed as application or API. Such code may serve e.g., to control a measurement application device, or to provide respective functions in a measurement application, which may be an example of a measurement application device and may be executed in a computer that is part of or coupled to the measurement system, like a cloud server.

Summing up, the system description data structure that may be used to centrally configure a measurement application system and evaluate the configuration for correctness or compliance, speeds up the configuration of the measurement application system and reduces the communication overhead in a measurement application system that is required for configuring a measurement application.

Applying the solution of the present disclosure also reduces the development effort when developing new measurement application devices, and reduces the requirements regarding processing power and memory in measurement application devices. For example, in known measurement application devices, the measurement application device is required to store details about any measurement probe that may be used with the respective measurement application device. With the solution of the present disclosure, the measurement application device may be provided with a configuration that is adapted to the respective measurement probe, without the need to store a database with information about all possible measurement probes in the measurement application device. This simplifies firmware development for the measurement application devices, and in some cases allows developing measurement application devices, like measurement probes, without processing elements, since all the configuration data may be provided via the system description data structure.

Further embodiments of the present disclosure are subject of the further dependent claims and of the following description, referring to the drawings.

In the following, the dependent claims referring directly or indirectly to claim 1 are described in more detail. For the avoidance of doubt, the features of the dependent claims relating to the method can be combined in all variations with each other and the disclosure of the description is not limited to the claim dependencies as specified in the claim set. Further, the features of the other independent claims may be combined with any of the features of the dependent claims relating to the method in all variations, wherein respective apparatus elements may perform the respective method steps.

In an embodiment, which can be combined with all other embodiments of the method mentioned above or below, the at least one of the constraints and the dependencies may comprise an expression regarding one of the properties, that during the evaluation evaluates to true or false.

The single expressions may be seen as a declarative description about what is necessary to achieve a consistent and valid configuration for the measurement application system. In embodiments, an expression may comprise multiple sections or sub-expressions, like maximum and minimum values and default values.

As already indicated above, the constraints or dependencies may comprise axioms or equations that may be evaluated during the step of evaluating.

Evaluating an expression to true or false may e.g., be performed by inputting values for the respective properties into the expression and asserting of the expression is fulfilled. For example, a constraint for a maximum gain value may be defined as G<100. Such an expression will evaluate to true if the value provided for this property is smaller than 100.

If all expressions evaluate to true, the system description data structure may be asserted to define a valid or consistent configuration of the measurement application system.

It is understood, that the step of evaluating the constraints and dependencies may be repeated for every user input. This allows quickly identifying incorrect or unallowed changes of properties that a user tries to perform.

The single expressions may also be enabled or disabled by logic combinations of variables or parameters.

In another embodiment, which can be combined with all other embodiments of the method mentioned above or below, the expression comprises links or relations to other properties.

A single expression may refer to a single property and may define e.g., limits and default values, as explained above. In embodiments, the expressions may also refer to other properties or parameters.

This allows modelling dependencies between different properties, and, therefore, also between different measurement application devices.

For a property the expression may be defined e.g., by including a reference to another properties value into a formula. For example, the formula for asserting if a property value is acceptable may include the value of the other property at any position. An exemplary formula for a property A may e.g., use the value of another property B like A<5*B, or A+B=100 or any other combination. Single properties may also be linked to properties of other measurement application devices.

With linked properties, it is possible that the value of a property changes after it is used in the calculation of another property. Therefore, evaluating may be repeated until the values of the properties do not change any more.

In a further embodiment, which can be combined with all other embodiments of the method mentioned above or below, the system description data structure may be provided as a structured document provided in a markup language.

The system description data structure may be provided in any one of different possible formats. For example, a respective XML schema or JSON schema, a Protocol Buffers schema, or any other schema definition may be defined for the system description data structure.

The system description data structure may be provided in a single file or document for the full measurement application system. In other embodiments, multiple files or documents may form the system description data structure. Such multiple files or documents may e.g., be provided as a hierarchical collection of documents, where a main document that describes the measurement application system references sub-ordinate documents where necessary or appropriate.

In a measurement application system, every single feature or capability may be provided with a section in a single-file system description data structure or with a dedicated file or document. Where multiple such features or capabilities are operatively linked together, the respective sections or documents may be linked accordingly, such that only valid combinations and configurations may be generated.

Such a collection of files or documents may be automatically created based on the knowledge of the measurement application devices that are present in the measurement application system. This information may be provided e.g., by the user or automatically via respective requests that may be sent to all measurement application devices via a respective data communication.

The system description data structure may comprise different sections. For example, a dedicated section may be provided for each measurement application device or for each property of a measurement application device. Each section may also comprise sub-sections. For example, a section for a specific property may comprise an “assertion” section that defines at least one of a variable that represents the respective property, an expression for evaluation of the respective property, and default values. In embodiments, different variants may be defined for each property and selection criteria for the respective variants may be defined.

In an example, a property may refer to an aspect ratio of a display device in the measurement application system. Different variants may, therefore, be provided for fixed ratio devices and for flexible ratio devices. The expression for calculating the aspect ratio may be provided as ar=x/y. Another section may be provided for “parameters” for the aspect ratio property. A single parameter may e.g., comprise a name, a standard value, a type, like float, integer, binary, a minimum value, and a maximum value.

In the system description data structure properties or sections of the structured document may have a limited visibility and accessibility. For example, single properties or the values of the properties may be defined as read only values that may not be changed by a user. Other properties or the values of the properties may be defined as auto-calculated values that may not be set by a user and will be calculated automatically, as is described in more detail below.

Properties or sections in the markup language document may be defined as visible or hidden. Hidden sections may define e.g., calculations or code generation rules that when executed prepare parameters of values for a measurement application device based on the current settings in the system description data structure. In an exemplary embodiment, code may be generated that may then be loaded into an FPGA of a measurement application device to perform specific measurement tasks with the respective measurement application device.

In another embodiment, which can be combined with all other embodiments of the method mentioned above or below, the system description data structure may comprise a determination rule for at least one of the properties that determines a value for the respective property.

The determination rule defines how the value for a respective property is to be calculated. Such properties may be presented to a user as read-only properties and the values of such properties may be recalculated any time the user changes another property on which the respective property depends.

In an example, a property A may be defined as A=10*B, wherein B may be the value of property B that a user may modify.

A determination rule may also be provided for properties that a user may modify. For such properties, the determination rule may in embodiments only be applied if the user-set value for the respective property violates the at least one of a constraint or a dependency of the respective property. The determination rule may in such an embodiment be used to automatically bring the system description data structure into a consistent state.

In an embodiment, which can be combined with all other embodiments of the method mentioned above or below, the system description data structure may comprise a definition of external parameters that are to be provided by a user, and prior to or during the evaluating the user may be prompted to input the external parameters, and evaluating may further be performed based on the provided external parameters.

The external parameters may refer to any type of physical parameter that may not be measured in the measurement application system but may be relevant for the measurement application. Such an external parameter may exemplarily comprise, but is not limited to, a temperature, especially an ambient temperature at the location of a device under test.

In another embodiment, which can be combined with all other embodiments of the method mentioned above or below, evaluating may comprise applying a computer algebra system to the constraints and dependencies.

As explained above, the expressions in the constraints or dependencies may be provided or comprise formulas. Such formulas may automatically be evaluated by a computer algebra system that is capable of solving the system of equations.

The system description data structure may also comprise hints to solve the system of equations that results from the system description data structure, especially in case that the system of equations is overdetermined.

In a further embodiment, which can be combined with all other embodiments of the method mentioned above or below, the system description data structure may further comprise at least one action definition that defines an action to be triggered in a respective measurement application device.

The action definitions may define single actions that need to be performed in the single measurement application devices that form the measurement application system in order to implement a measurement application.

Such actions may refer to starting a signal generation in a signal generation measurement application device, starting a signal recording in a signal recording measurement application device, or performing any other action or function that is present in the measurement application system.

In embodiments, the action definitions may relate to other action definitions, and e.g., define that a specific action needs to be initiated, or performed, or terminated prior to another action. For example, a signal generation may need to be running prior to starting a measurement.

In another embodiment, which can be combined with all other embodiments of the method mentioned above or below, the method may further comprise transmitting the system description data structure to the one or more measurement application devices that are present in the measurement application system, and performing the actions defined in the system description data structure in the one or more measurement application devices.

With the system description data structure comprising action definitions, the system description data structure comprises all the information that is required to configure the measurement application devices in a measurement application system, and to perform a measurement with the measurement application system.

Therefore, after transmitting the system description data structure to the single measurement application devices, the measurement may be performed based on the action definitions.

The transmission of the system description data structure may be performed by directly sending the system description data structure to the measurement application devices, or at least the section of the system description data structure that is relevant for the respective measurement application device.

Alternatively, the configuration device may comprise a logic to process the system description data structure, and configure and control the single measurement application devices via other means, like for example an SCPI interface. Using e.g., SCPI allows using the solution of the present disclosure with measurement application devices that may not directly process the system description data structure while preserving the advantages during creating the configuration for the measurement application system.

In an embodiment, which can be combined with all other embodiments of the method mentioned above or below, the method may further comprises receiving the user input for at least one of the properties as SCPI command, parsing the received SCPI command, and setting the at least one of the properties according to the parsed SCPI command.

SCPI (“Standard Commands for Programmable Instruments”) is a standardized command set for controlling measurement application devices.

A user may already have prepared a plurality of SCPI programs for his measurement application devices that he may want to reuse.

By providing the ability, especially in the configuration device, to receive and parse SCPI commands, it is possible to reuse SCPI programs that a user may already have prepared. At the same time, all the evaluation may be performed in the configuration device directly after receiving the SCPI program. Therefore, the evaluation may be performed quickly without transmitting the complete SCPI program to all the measurement application devices that form the measurement application system.

### BRIEF DESCRIPTION OF THE DRAWINGS

For a more complete understanding of the present disclosure and advantages thereof, reference is now made to the following description taken in conjunction with the accompanying drawings. The disclosure is explained in more detail below using exemplary embodiments which are specified in the schematic figures of the drawings, in which:

FIG. 1 shows a flow diagram of an embodiment of a method according to the present disclosure;

FIG. 2 shows a flow diagram of another embodiment of a method according to the present disclosure;

FIG. 3 shows a flow diagram of another embodiment of a method according to the present disclosure;

FIG. 4 shows a flow diagram of another embodiment of a method according to the present disclosure;

FIG. 5 shows a flow diagram of another embodiment of a method according to the present disclosure;

FIG. 6 shows a block diagram of an embodiment of a measurement application system configuration system according to the present disclosure;

FIG. 7 shows a block diagram of another embodiment of a measurement application system configuration system according to the present disclosure;

FIG. 8 shows a block diagram of another embodiment of a measurement application system configuration system according to the present disclosure;

FIG. 9 shows a block diagram of another embodiment of a measurement application system configuration system according to the present disclosure;

FIG. 10 shows a block diagram of another embodiment of a measurement application system configuration system according to the present disclosure;

FIG. 11 shows a block diagram of another embodiment of a measurement application system configuration system according to the present disclosure;

FIG. 12 shows a block diagram of another embodiment of a measurement application system configuration system according to the present disclosure;

FIG. 13 shows a block diagram of an embodiment of a measurement application device that may be used with the disclosure of the present disclosure; and

FIG. 14 shows another block diagram of an embodiment of a measurement application device that may be used with the disclosure of the present disclosure,

In the figures like reference signs denote like elements unless stated otherwise.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

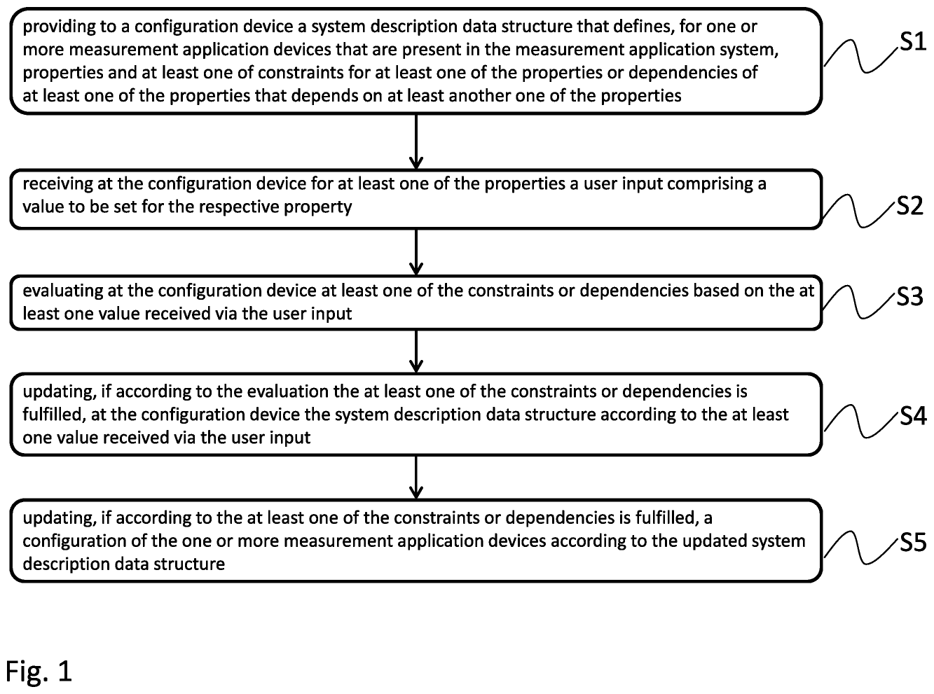

FIG. 1 shows a flow diagram of a method for configuring a measurement application system.

The method comprises providing S1 to a configuration device a system description data structure that defines, for one or more measurement application devices that are present in the measurement application system, properties and at least one of constraints for at least one of the properties, and dependencies of at least one of the properties that depends on at least another one of the properties.

The constraints and dependencies are optional elements of the system description data structure, and allow verifying a configuration of the measurement application system prior to transmitting any settings to the measurement application devices. The system description data structure may in embodiments be provided as a structured document provided in a markup language.

The method further comprises receiving S2 at the configuration device for at least one of the properties a user input comprising a value to be set for the respective property, and evaluating S3 at the configuration device at least one, especially all, of the constraints or dependencies based on the at least one value received via the user input.

The system description data structure may comprise a determination rule for at least one of the properties that determines a value for the respective property. Such a determination rule may comprise a formula or any other expression that allows automatically determining a value for the respective property. This allows automatically determining allowable values for properties that are not actively set by a user.

If according to the evaluation the at least one, especially all, of the constraints or dependencies is fulfilled, the method comprises updating S4 at the configuration device the system description data structure according to the at least one value received via the user input; and updating S5 a configuration of the one or more measurement application devices according to the updated system description data structure.

In embodiments, at least one of the constraints and the dependencies may comprise an expression regarding one of the properties, that during the evaluation evaluates to true or false. In addition, such expressions may comprise links or relations to other properties.

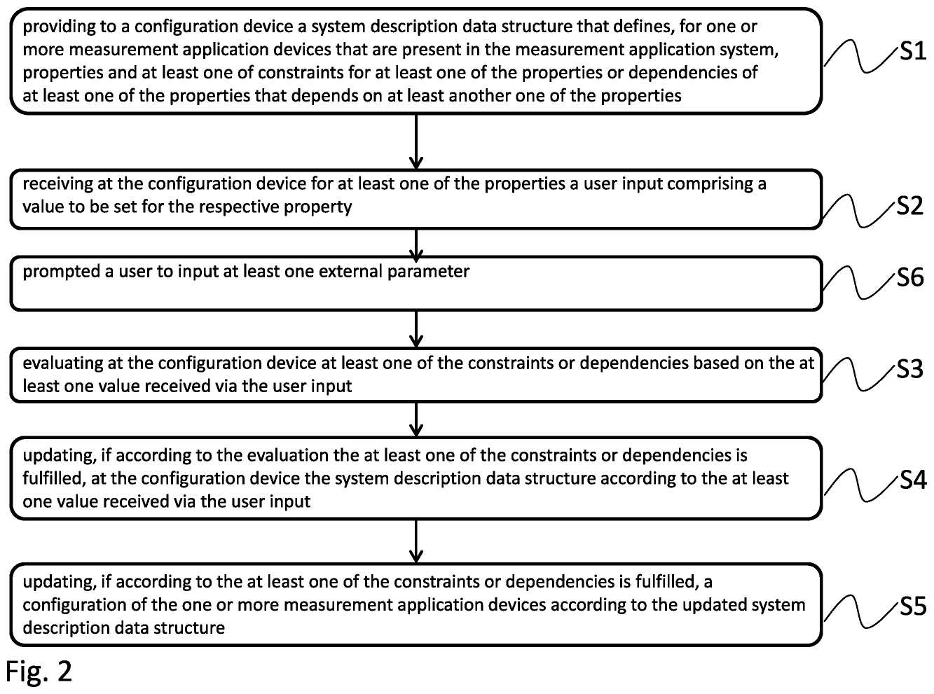

FIG. 2 shows a flow diagram of a method for configuring a measurement application system. The method of FIG. 2 is based on the method of FIG. 1. Therefore, the method of FIG. 2 also comprises the steps S1-S5. The above-provided explanations regarding the method of FIG. 1 apply mutatis mutandis to the method of FIG. 2.

The method of FIG. 2 comprises after receiving S2 a user input comprising a value to be set for a property, prompting S6 a user to input at least one external parameter. It is understood, that the user may also be prompted prior to receiving the user input or while evaluating S3.

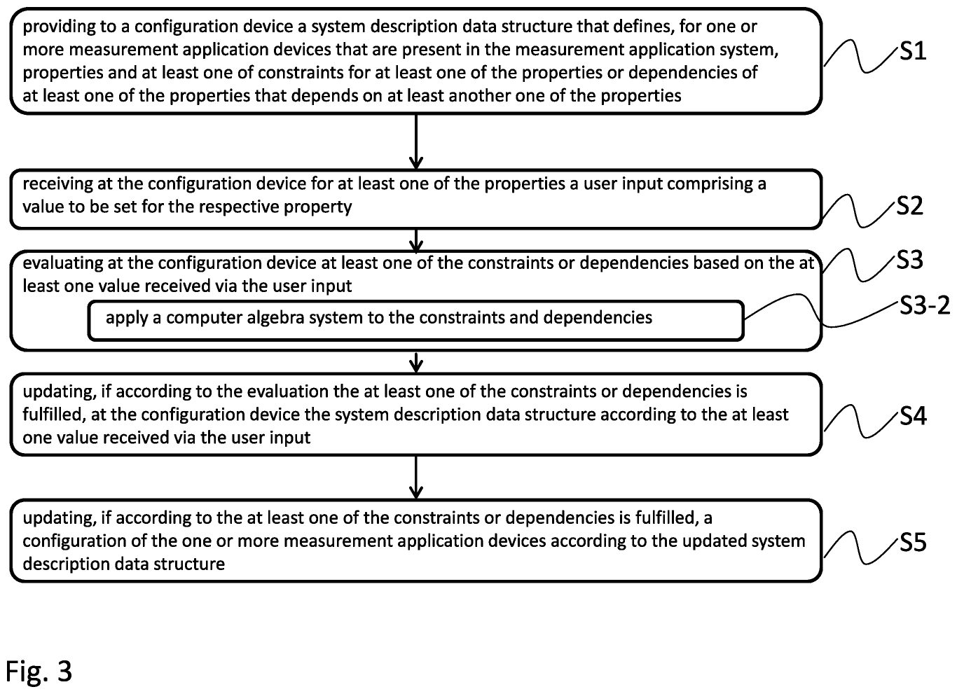

FIG. 3 shows a flow diagram of a method for configuring a measurement application system. The method of FIG. 3 is based on the method of FIG. 1. Therefore, the method of FIG. 3 also comprises the steps S1-S5. The above-provided explanations regarding the method of FIG. 1 apply mutatis mutandis to the method of FIG. 3. The method shown in FIG. 3 may be combined with any of the features of the method of FIG. 2.

The method of FIG. 3 further comprises in the step of evaluating S3, applying S3-2 a computer algebra system to the constraints and dependencies i.e., a system of equations that is formed based on the constraints and dependencies.

This allows easily determining if a measurement system configured according to the user-provided settings fulfills all constraints and dependencies.

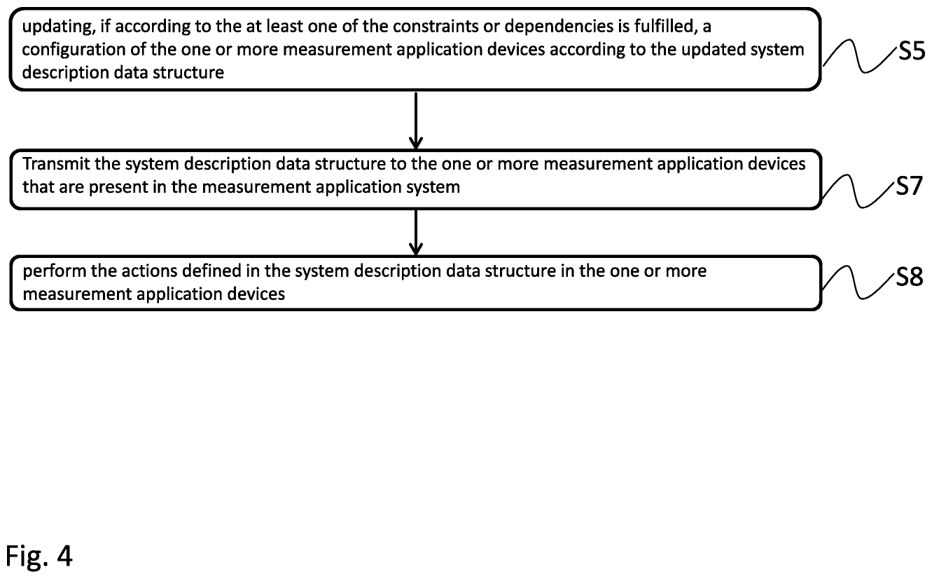

FIG. 4 shows a flow diagram of a method for configuring a measurement application system. The method of FIG. 4 is based on the method of FIG. 1. Therefore, the method of FIG. 4 also comprises the steps S1-S5, although for sake of clarity only step S5 is shown. The above-provided explanations regarding the method of FIG. 1 apply mutatis mutandis to the method of FIG. 4. The method shown in FIG. 4 may be combined with any of the features of the methods of FIGS. 2 and 3.

The method of FIG. 4 further comprises after updating S5, transmitting S7 the system description data structure to the one or more measurement application devices that are present in the measurement application system, and performing S8 the actions defined in the system description data structure in the one or more measurement application devices.

This allows controlling the measurement application devices directly based on the updated system description data structure.

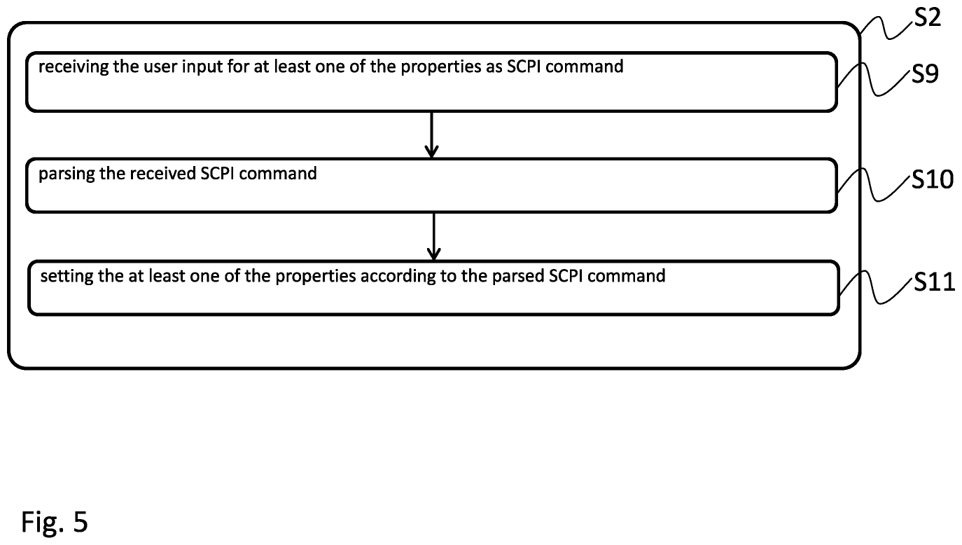

FIG. 5 shows a flow diagram of a method for configuring a measurement application system, especially a detailed view of the step of receiving S2 a user input comprising a value to be set. The method of FIG. 5 is based on the method of FIG. 1. Therefore, the method of FIG. 4 may also comprises the steps S1, S3, S4 and S5, although for sake of clarity only step S2 is shown. The above-provided explanations regarding the method of FIG. 1 apply mutatis mutandis to the method of FIG. 5. The method shown in FIG. 5 may be combined with any of the features of the methods of FIGS. 2 to 4.

The method of FIG. 5 further comprises for receiving S2 the user input receiving S9 the user input for at least one of the properties as SCPI command, parsing S10 the received SCPI command, and setting S11 the at least one of the properties according to the parsed SCPI command.

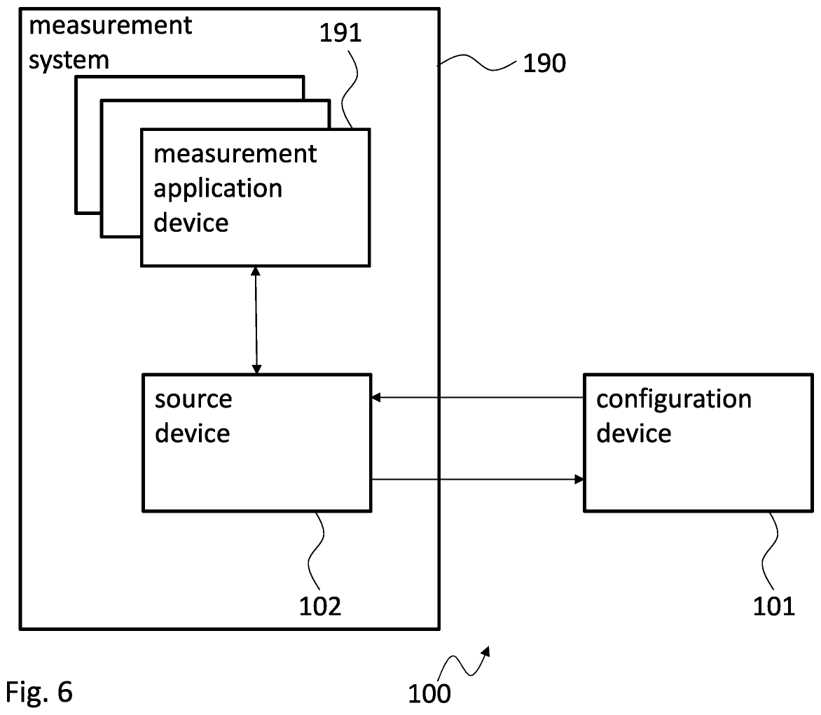

FIG. 6 shows a block diagram of a measurement application system configuration system 100. The measurement application system configuration system 100 comprises a configuration device 101 that is coupled to a source device 102. In the measurement application system configuration system 100, the source device 102 is optionally provided in a measurement application system 190 that comprises at least one measurement application device 191. The measurement application devices 191 are communicatively coupled to the source device 102. The source device 102 may collect the relevant information e.g., respective sub-sections of the system description data structure from the single measurement application devices 191, and provide the full system description data structure to the configuration device 101.

It is understood, that the configuration device 101 may comprise or may be provided in or as part of at least one of a dedicated processing element e.g., a processing unit, a microcontroller, a field programmable gate array, FPGA, a complex programmable logic device, CPLD, an application specific integrated circuit, ASIC, or the like. A respective program or configuration may be provided to implement the required functionality. The configuration device 101 may at least in part also be provided as a computer program product comprising computer readable instructions that may be executed by a processing element. In a further embodiment, the configuration device 101 may be provided as addition or additional function or method to the firmware or operating system of a processing element that is already present in the respective application as respective computer readable instructions. Such computer readable instructions may be stored in a memory that is coupled to or integrated into the processing element. The processing element may load the computer readable instructions from the memory and execute them. In addition, it is understood, that any required supporting or additional hardware may be provided like e.g., a power supply circuitry and clock generation circuitry. Other embodiments of the configuration device 101 disclosed herein may also be used in the measurement application system configuration system 100. The explanations provided for the configuration device 101 also apply mutatis mutandis to the source device 102.

In embodiments, the source device 102 may be provided as a single device. Such a device may communicatively couple to measurement application devicesn191 and generate the system description data structure based on information received from the single measurement application devices 192.

In embodiments, the measurement application devices 191 may also be directly coupled to the configuration device 101 instead of or in addition to the source device 102. In such embodiments, the measurement application devices 191 may directly provide the sub-sections of the system description data structure to the configuration device 101.

Although not shown, the configuration device 101 and the source device 102 may comprise respective communication interfaces for communicating with each other and the measurement application devices 191.

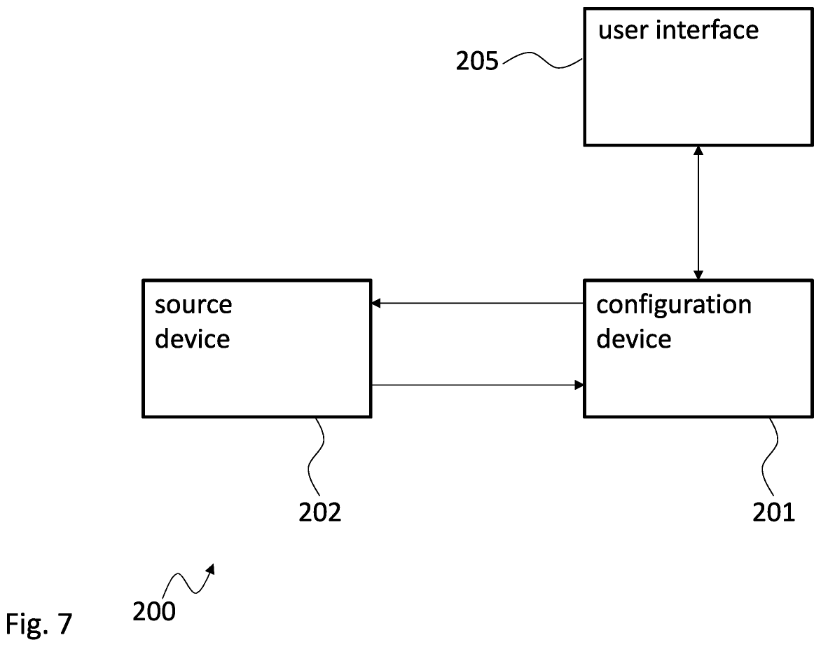

FIG. 7 shows a block diagram of a measurement application system configuration system 200. The measurement application system configuration system 200 is based on the measurement application system configuration system 100. Therefore, the measurement application system configuration system 200 comprises a configuration device 201 that is coupled to a source device 202. In the measurement application system configuration system 200, the measurement application devices are not explicitly shown. It is understood, that the source device 202 may be part of a measurement application system 190 as shown in FIG. 1.

The measurement application system configuration system 200 further comprises a user interface 205 that is coupled to the configuration device 201. In embodiments that comprise a program-based or application-based configuration device 201, the user interface 205 may be a user interface provided by such a program or application. In other embodiments, the user interface 205 may be a dedicated user interface.

The system description data structure may comprise a definition of external parameters that are to be provided by a user. The configuration device 201 may use the user interface 205 to prompt a user to input such external parameters.

Of course, the user interface 205 may be used for any other interaction by the user with the measurement application system configuration system 200 e.g., for providing the values for the single properties.

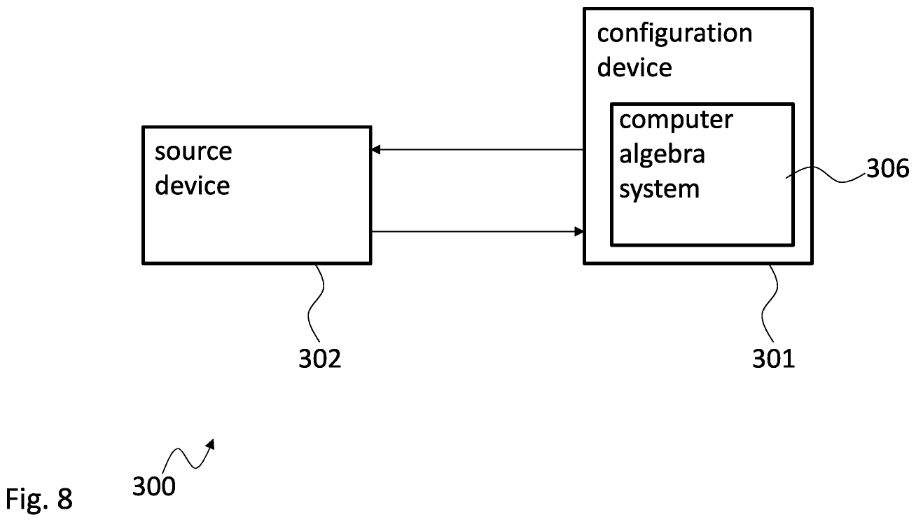

FIG. 8 shows a block diagram of a measurement application system configuration system 300. The measurement application system configuration system 300 is based on the measurement application system configuration system 100. Therefore, the measurement application system configuration system 300 comprises a configuration device 301 that is coupled to a source device 302. In the measurement application system configuration system 300, the measurement application devices are not explicitly shown. It is understood, that the source device 302 may be part of a measurement application system 190 as shown in FIG. 1.

In the measurement application system configuration system 300, the configuration device 301 comprises a computer algebra system 306 for solving a system of equations that is generated based on the constraints and dependencies that are provided in the system description data structure.

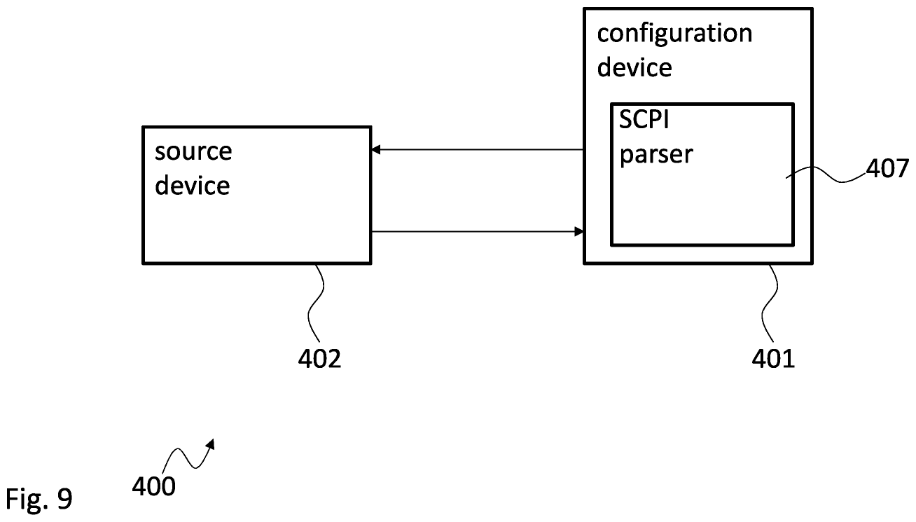

FIG. 9 shows a block diagram of a measurement application system configuration system 400. The measurement application system configuration system 400 is based on the measurement application system configuration system 100. Therefore, the measurement application system configuration system 300 comprises a configuration device 401 that is coupled to a source device 402. In the measurement application system configuration system 400, the measurement application devices are not explicitly shown. It is understood, that the source device 402 may be part of a measurement application system 190 as shown in FIG. 1.

In the measurement application system configuration system 400, the configuration device 401 comprises an SCPI parser 407. The SCPI parser 407 may alternatively also be provided in a user interface. The SCPI parser 407 serves for parsing and processing any SCPI command that may be received by the configuration device 401 instead of a user input that directly provides a value for a property.

With the SCPI parser 407, the configuration device 401 may be used to parse any existing SCPI program that may have already been developed by a user for a prior art measurement system. With the SCPI parser 407 such programs may easily be reused in a measurement application system configuration system 400 according to the present disclosure, and may quickly be evaluated in the configuration device 401 for conformance with all constraints and dependencies.

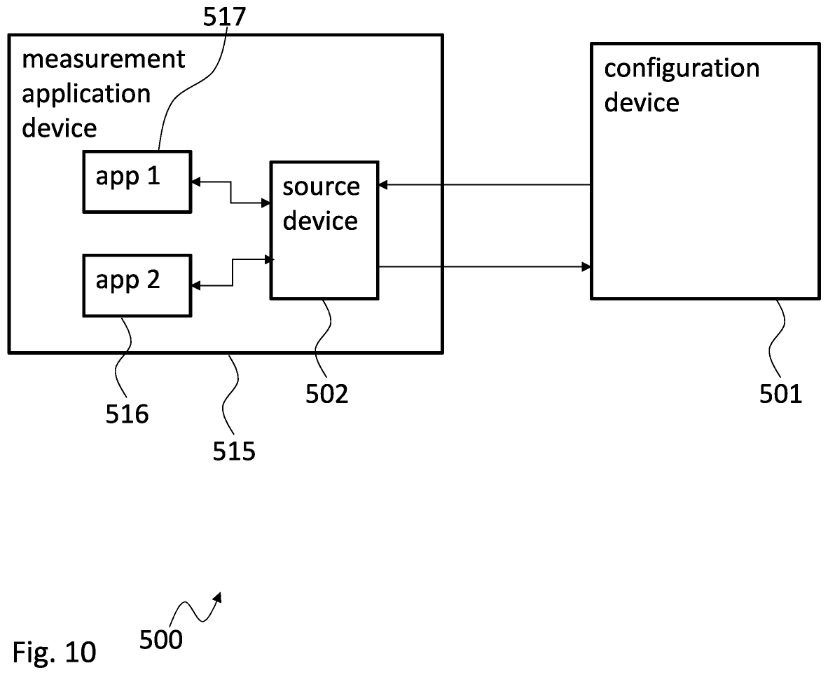

FIG. 10 shows a block diagram of a measurement application system configuration system 500. The measurement application system configuration system 500 is based on the measurement application system configuration system 100. Therefore, the measurement application system configuration system 500 comprises a configuration device 501 that is coupled to a source device 502. In the measurement application system configuration system 500, the measurement application devices are not explicitly shown and may be omitted. It is understood, that the source device 502 may be part of a measurement application system 190 as shown in FIG. 1.

In the measurement application system configuration system 500, the source device 502 is provided in a measurement application device 515, and is coupled to two applications 516, 517, wherein only one application or more than two applications 516, 517 are also possible. The term “application” in this context is to be understood as any entity, program based or hardware based, that may provide the source device 502 with a at least part of the system description data structure, especially a sub-section of the system description data structure that defines properties, constraints, and dependencies for a specific function of the measurement application device 515. Therefore, two applications may provide information for the same measurement application device 515, if the respective measurement application device is capable of performing the respective functions.

In embodiments, the source device 502 may be provided externally to the measurement application device 515, and may be coupled to multiple measurement application devices. In such embodiments, different applications in the measurement application devices may provide the respective information to the source device 502.

In other embodiments, the source device 502 may be provided in one of the measurement application devices of a measurement application system, and may be communicatively coupled to the other measurement application devices of the measurement application system to retrieve the respective information.

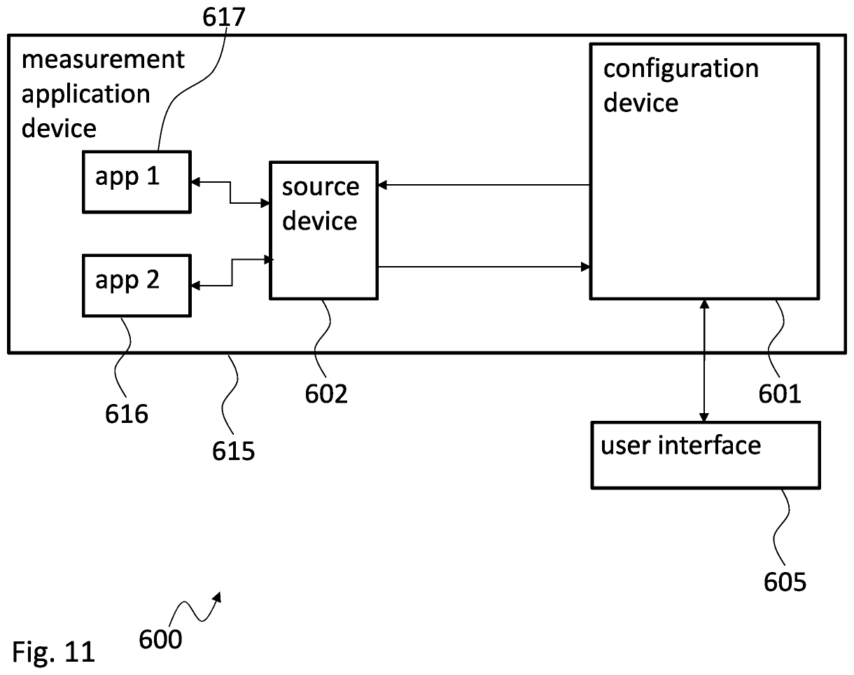

FIG. 11 shows a block diagram of a measurement application system configuration system 600. The measurement application system configuration system 600 is based on the measurement application system configuration system 100. Therefore, the measurement application system configuration system 600 comprises a configuration device 601 that is coupled to a source device 602. In the measurement application system configuration system 600, the measurement application devices are not explicitly shown and may be omitted. It is understood, that the source device 602 may be part of a measurement application system 190 as shown in FIG. 1.

In the measurement application system configuration system 600, the source device 602 is provided in a measurement application device 615, and is coupled to two applications 616, 617, wherein only one application or more than two applications 616, 617 are also possible. The term “application” in this context is to be understood as explained above. The explanations provided regarding the measurement application system configuration system 500 apply to the measurement application system configuration system 600 mutatis mutandis.

In the measurement application system configuration system 600, the configuration device 601 is provided as part of the measurement application device 615. In such an embodiment, the configuration device 601 may be coupled to other measurement application devices via a communication interface of the measurement application device 615.

In the measurement application system configuration system 600, a dedicated user interface 605 is shown that is coupled to the configuration device 601. Such a user interface 605 may be provided as application that is executed on a user device e.g., an HTML and/or JavaScript application, or a native application. In embodiments, the user interface 605 may be integrated into the measurement application device 615.

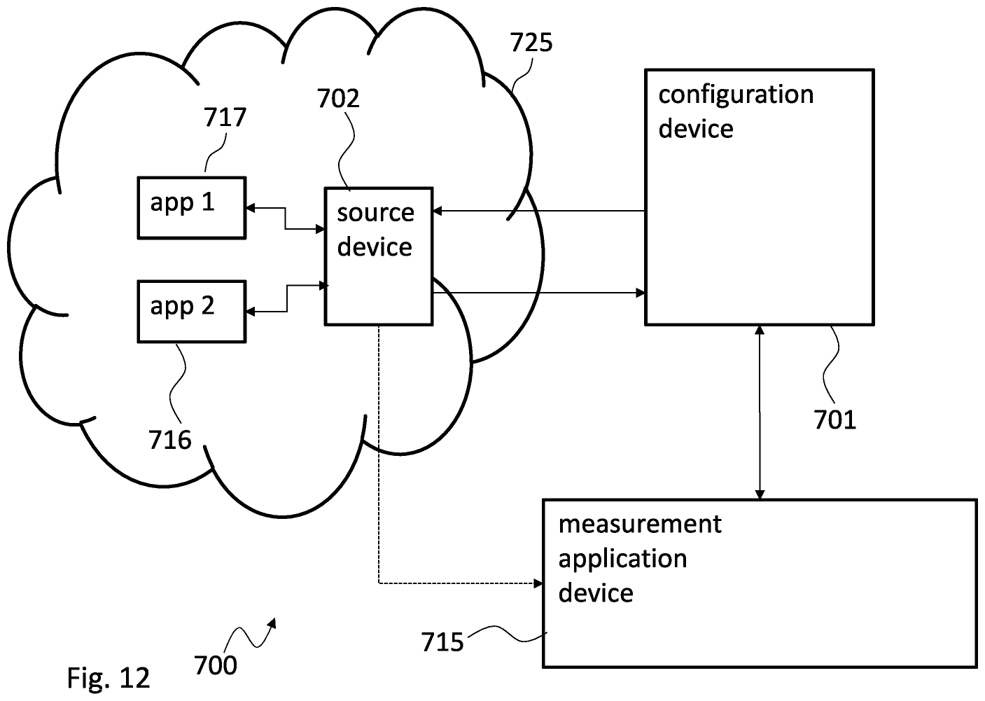

FIG. 12 shows a block diagram of a measurement application system configuration system 700. The measurement application system configuration system 700 is based on the measurement application system configuration system 100. Therefore, the measurement application system configuration system 700 comprises a configuration device 701 that is coupled to a source device 702. In the measurement application system configuration system 700, the measurement application devices are not explicitly shown.

In the measurement application system configuration system 700, the source device 702 is provided in a server or cloud system 725. The applications 716, 717 are also provided in the cloud system 725. Further, a measurement application device 715 is provided that is coupled to the configuration device 701, and the source device 702.

The configuration device 701 may in this embodiment be provided e.g., as an HTML/JavaScript application that is executed in a browser on a user computer or as a native application.

In embodiments of the measurement application system configuration system 700 that comprise a server or cloud for providing the source device 702 and storing the system description data structure e.g., in the form of respective applications, the configuration device 701 may retrieve from the measurement application device 715 respective IDs that may be provided to the source device 702 for identifying the required applications or system description data structure parts. Such information may also be provided from the measurement application device 715 directly to the source device 702.

It is understood, that single elements of all embodiments disclosed herein may be freely combined into new embodiments. For example, the SCPI parser may be combined with any one of a user interface for receiving external parameters, and with the computer algebra system.

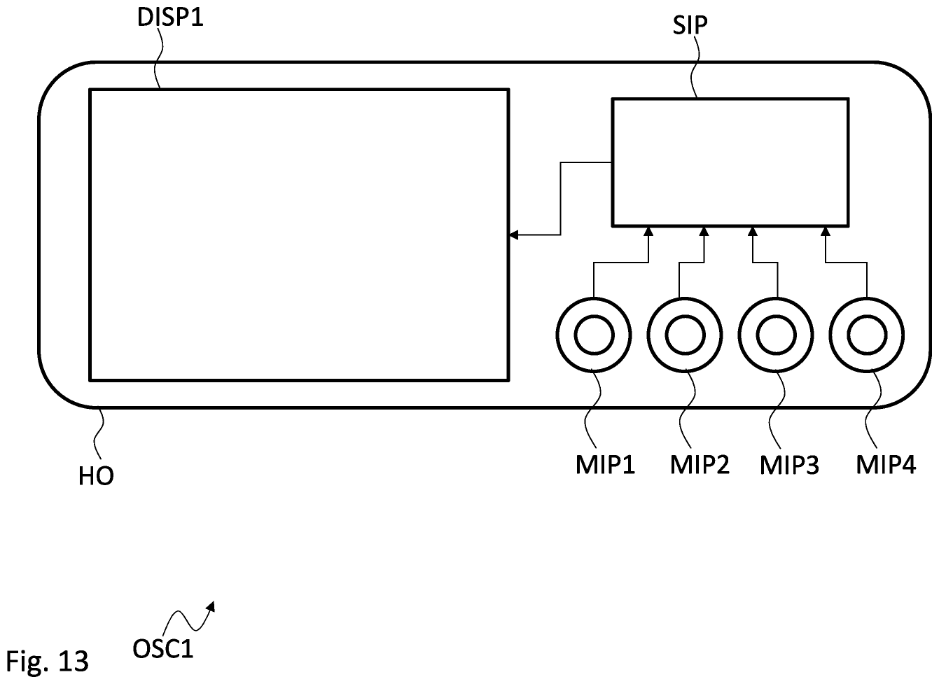

FIG. 13 shows a block diagram of an oscilloscope OSC1 that may be used with an embodiment of a method according to the present disclosure.

The oscilloscope OSC1 comprises a housing HO that accommodates four measurement inputs MIP1, MIP2, MIP3, MIP4 that are coupled to a signal processor SIP for processing any measured signals. The signal processor SIP is coupled to a display DISP1 for displaying the measured signals to a user.

The signal processor SIP may provide any embodiment of the source device as disclosed herein. Although not explicitly shown, a communication interface of the oscilloscope OSC1 may serve for communicating the signal processor SIP with an external configuration device. In embodiments, the configuration device may also be provided in the signal processor SIP e.g., as respective application.

Although not explicitly shown, it is understood, that the oscilloscope OSC1 may also comprise signal outputs that may also be coupled to the differential measurement probe. Such signal outputs may for example serve to output calibration signals. Such calibration signals allow calibrating the measurement setup prior to performing any measurement. The process of calibrating and correcting any measurement signals based on the calibration may also be called de-embedding and may comprise applying respective algorithms on the measured signals.

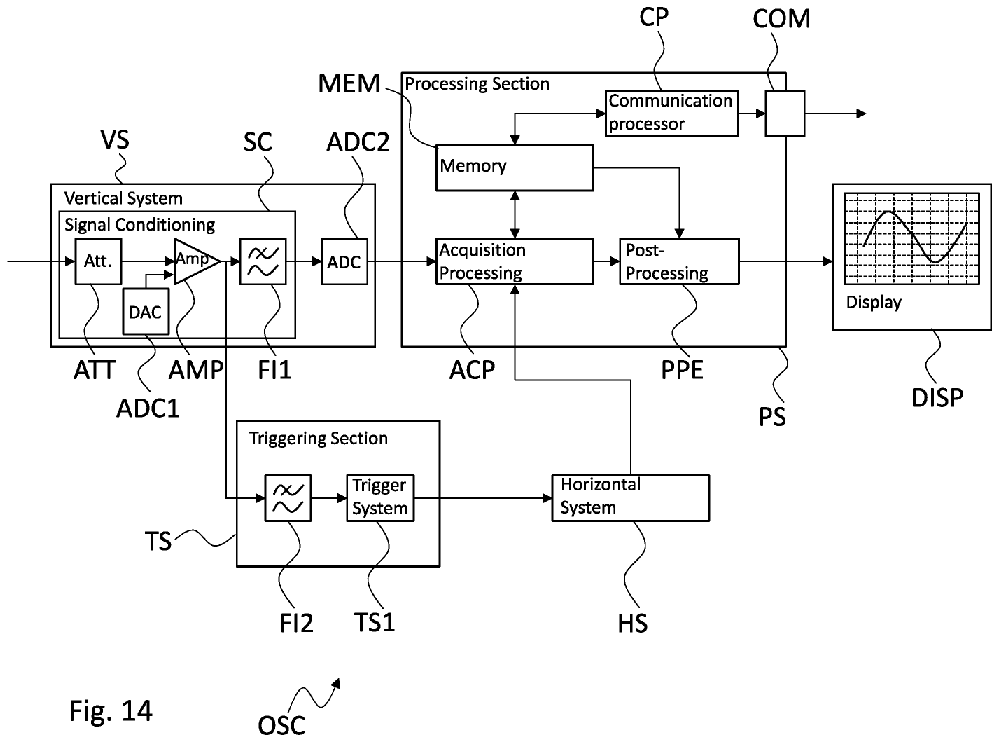

FIG. 14 shows a block diagram of an oscilloscope OSC that may be an implementation of a measurement application device to be used with the present disclosure. The oscilloscope OSC is implemented as a digital oscilloscope. However, the present disclosure may also be implemented with any other type of oscilloscope.

The oscilloscope OSC exemplarily comprises five general sections, the vertical system VS, the triggering section TS, the horizontal system HS, the processing section PS and the display DISP. It is understood, that the partitioning into five general sections is a logical partitioning and does not limit the placement and implementation of any of the elements of the oscilloscope OSC in any way.

The vertical system VS mainly serves for offsetting, attenuating and amplifying a signal to be acquired. The signal may for example be modified to fit in the available space on the display DISP or to comprise a vertical size as configured by a user.

To this end, the vertical system VS comprises a signal conditioning section SC with an attenuator ATT and a digital-to-analog-converter DAC that are coupled to an amplifier AMP1. The amplifier AMP1 is coupled to a filter FI1, which in the shown example is provided as a low pass filter. The vertical system VS also comprises an analog-to-digital converter ADC1 that receives the output from the filter FI1 and converts the received analog signal into a digital signal.

The attenuator ATT and the amplifier AMP1 serve to scale the amplitude of the signal to be acquired to match the operation range of the analog-to-digital converter ADC1. The digital-to-analog-converter DAC1 serves to modify the DC component of the input signal to be acquired to match the operation range of the analog-to-digital converter ADC1. The filter FI1 serves to filter out unwanted high frequency components of the signal to be acquired.

The triggering section TS operates on the signal as provided by the amplifier AMP. The triggering section TS comprises a filter FI2, which in this embodiment is implemented as a low pass filter. The filter FI2 is coupled to a trigger system TS1.

The triggering section TS serves to capture predefined signal events and allows the horizontal system HS to e.g., display a stable view of a repeating waveform, or to simply display waveform sections that comprise the respective signal event. It is understood, that the predefined signal event may be configured by a user via a user input of the oscilloscope OSC.

Possible predefined signal events may for example include, but are not limited to, when the signal crosses a predefined trigger threshold in a predefined direction i.e., with a rising or falling slope. Such a trigger condition is also called an edge trigger. Another trigger condition is called “glitch triggering” and triggers, when a pulse occurs in the signal to be acquired that has a width that is greater than or less than a predefined amount of time.

In order to allow an exact matching of the trigger event and the waveform that is shown on the display DISP, a common time base may be provided for the analog-to-digital converter ADC1 and the trigger system TS1.

It is understood, that although not explicitly shown, the trigger system TS1 may comprise at least one of configurable voltage comparators for setting the trigger threshold voltage, fixed voltage sources for setting the required slope, respective logic gates like e.g., a XOR gate, and FlipFlops to generate the triggering signal.

The triggering section TS is exemplarily provided as an analog trigger section. It is understood, that the oscilloscope OSC may also be provided with a digital triggering section. Such a digital triggering section will not operate on the analog signal as provided by the amplifier AMP but will operate on the digital signal as provided by the analog-to-digital converter ADC1.

A digital triggering section may comprise a processing element, like a processor, a DSP, a CPLD, an ASIC or an FPGA to implement digital algorithms that detect a valid trigger event.

The horizontal system HS is coupled to the output of the trigger system TS1 and mainly serves to position and scale the signal to be acquired horizontally on the display DISP.

The oscilloscope OSC further comprises a processing section PS that implements digital signal processing and data storage for the oscilloscope OSC. The processing section PS comprises an acquisition processing element ACP that is couple to the output of the analog-to-digital converter ADC1 and the output of the horizontal system HS as well as to a memory MEM and a post processing element PPE.

The acquisition processing element ACP manages the acquisition of digital data from the analog-to-digital converter ADC1 and the storage of the data in the memory MEM. The acquisition processing element ACP may for example comprise a processing element with a digital interface to the analog-to-digital converter ADC2 and a digital interface to the memory MEM. The processing element may for example comprise a microcontroller, a DSP, a CPLD, an ASIC or an FPGA with respective interfaces. In a microcontroller or DSP, the functionality of the acquisition processing element ACP may be implemented as computer readable instructions that are executed by a CPU. In a CPLD or FPGA the functionality of the acquisition processing element ACP may be configured in to the CPLD or FPGA opposed to software being executed by a processor.

The processing section PS further comprises a communication processor CP and a communication interface COM.

The communication processor CP may be a device that manages data transfer to and from the oscilloscope OSC. The communication interface COM for any adequate communication standard like for example, Ethernet, WIFI, Bluetooth, NFC, an infra-red communication standard, and a visible-light communication standard.

The communication processor CP is coupled to the memory MEM and may use the memory MEM to store and retrieve data.

Of course, the communication processor CP may also be coupled to any other element of the oscilloscope OSC to retrieve device data or to provide device data that is received from the management server.

The post processing element PPE may be controlled by the acquisition processing element ACP and may access the memory MEM to retrieve data that is to be displayed on the display DISP. The post processing element PPE may condition the data stored in the memory MEM such that the display DISP may show the data e.g., as waveform to a user. The post processing element PPE may also realize analysis functions like cursors, waveform measurements, histograms, or math functions.

The display DISP controls all aspects of signal representation to a user, although not explicitly shown, may comprise any component that is required to receive data to be displayed and control a display device to display the data as required.

Any embodiment of the source device as disclosed herein may be provided in the processing section PS. The communication interface COM of the processing section PS may serve for communicating such a source device with an external configuration device. In embodiments, the configuration device may also be provided in the processing section e.g., as respective application that is executed by a respective processing element.

It is understood, that even if it is not shown, the oscilloscope OSC may also comprise a user interface for a user to interact with the oscilloscope OSC. Such a user interface may comprise dedicated input elements like for example knobs and switches. At least in part the user interface may also be provided as a touch sensitive display device.

It is understood, that all elements of the oscilloscope OSC that perform digital data processing may be provided as dedicated elements. As alternative, at least some of the above-described functions may be implemented in a single hardware element, like for example a microcontroller, DSP, CPLD or FPGA. Generally, the above-describe logical functions may be implemented in any adequate hardware element of the oscilloscope OSC and not necessarily need to be partitioned into the different sections explained above.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the disclosure that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The abstract of the disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

While exemplary embodiments are described above, it is not intended that these embodiments describe all possible forms of the disclosure. Rather, the words used in the specification are words of description rather than limitation, and it is understood that various changes may be made without departing from the spirit and scope of the disclosure. Additionally, the features of various implementing embodiments may be combined to form further embodiments of the disclosure.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### LIST OF REFERENCE SIGNS

100, 200, 300, 400, 500, 600, 700 measurement application system configuration system
101, 201, 301, 401, 501, 601, 701 source device
102, 202, 302, 402, 502, 602, 702 configuration device
205, 605 user interface
306 computer algebra system
407 SCPI parser
515, 615, 715 measurement application device
516, 517, 616, 617, 716, 171 application
725 (cloud-)server
190 measurement application system
191 measurement application device
OSC1 oscilloscope
HO housing
MIP1, MIP2, MIP3, MIP4 measurement input
SIP signal processing
DISP1 display
OSC oscilloscope
VS vertical system
SC signal conditioning
ATT attenuator
DAC1 analog-to-digital converter
AMP1 amplifier
FI1 filter
ADC1 analog-to-digital converter
TS triggering section
AMP2 amplifier
FI2 filter
TS1 trigger system
HS horizontal system
PS processing section
ACP acquisition processing element
MEM memory
PPE post processing element
DISP display

What is claimed is:

1. A method for configuring a measurement application system, the method comprising:
providing to a configuration device a system description data structure that defines, for one or more measurement application devices that are present in the measurement application system, properties and at least one of constraints for at least one of the properties, and dependencies of at least one of the properties that depends on at least another one of the properties;
receiving at the configuration device for at least one of the properties a user input comprising a value to be set for the respective property;
evaluating at the configuration device at least one of the constraints or dependencies based on the at least one value received via the user input;
updating, if according to the evaluation the at least one of the constraints or dependencies is fulfilled, at the configuration device the system description data structure according to the at least one value received via the user input; and
updating, if according to the evaluation the at least one of the constraints or dependencies is fulfilled, a configuration of the one or more measurement application devices according to the updated system description data structure.

2. The method according to claim 1, wherein at least one of the constraints and the dependencies comprises an expression regarding one of the properties, that during the evaluation evaluates to true or false.

3. The method according to claim 2, wherein the expression comprises links or relations to other properties.

4. The method according to claim 1, wherein the system description data structure is provided as a structured document provided in a markup language.

5. The method according to claim 1, wherein the system description data structure comprises a determination rule for at least one of the properties that determines a value for the respective property.

6. The method according to claim 1, wherein the system description data structure comprises a definition of external parameters that are to be provided by a user; and
wherein prior to or during the evaluating the user is prompted to input the external parameters; and
wherein evaluating is further performed based on the provided external parameters.

7. The method according to claim 1, wherein evaluating comprises applying a computer algebra system to the constraints and dependencies.

8. The method according to claim 1, wherein the system description data structure further comprises at least one action definition that defines an action to be triggered in a respective measurement application device.

9. The method according to claim 8, further comprising:
transmitting the system description data structure to the one or more measurement application devices that are present in the measurement application system; and
performing the actions defined in the system description data structure in the one or more measurement application devices.

10. The method according to claim 1, further comprising:
receiving the user input for at least one of the properties as a SCPI command;
parsing the received SCPI command; and
setting the at least one of the properties according to the parsed SCPI command.

11. A measurement application system configuration system comprising:
a source device configured to provide a system description data structure that defines, for one or more measurement application devices of a measurement application system, properties and at least one of constraints for at least one of the properties, and dependencies of at least one of the properties that depends on at least another one of the properties; and
a configuration device configured to:
receive for at least one of the properties a user input comprising a value to be set for the respective property;
evaluate at least one of the constraints or dependencies based on the at least one value received via the user input;
update, if according to the evaluation the at least one of the constraints or dependencies is fulfilled, the system description data structure according to the at least one value received via the user input; and
transmit, if according to the evaluation the at least one of the constraints or dependencies is fulfilled, an updated configuration to the one or more measurement application devices according to the updated system description data structure.

12. The measurement application system according to claim 11, wherein at least one of the constraints and the dependencies comprises an expression regarding one of the properties, that during the evaluation evaluates to true or false.

13. The measurement application system according to claim 12, wherein the expression comprises links or relations to other properties.

14. The measurement application system according to claim 11, wherein the system description data structure comprises a structured document provided in a markup language; and
wherein the configuration device is configured to process the structured document.

15. The measurement application system according to claim 11, wherein the system description data structure comprises a determination rule for at least one of the properties that determines a value for the respective property; and
wherein the configuration device is configured to process the determination rule.

16. The measurement application system according to claim 11, wherein the system description data structure comprises a definition of external parameters that are to be provided by a user; and
wherein the configuration device is configured to prompt the user to input the external parameters prior to or during performing the evaluation, and to perform the evaluation further based on the provided external parameters.

17. The measurement application system according to claim 11, wherein the configuration device is configured to apply a computer algebra system to the constraints and dependencies for evaluating the at least one of the constraints or dependencies.

18. The measurement application system according to claim 11, wherein the system description data structure further comprises at least one action definition that defines an action to be triggered in a respective measurement application device; and
wherein the configuration device is configured to process the action definition and generate respective control commands for the one or more measurement application devices, or wherein the one or more measurement application devices are configured to process the action definition.

19. The measurement application system according to claim 18, wherein the configuration device is further configured to:
transmit the system description data structure to the one or more measurement application devices;
wherein the one or more measurement application devices are configured to perform the actions defined in the system description data structure.

20. The measurement application system according to claim 11, wherein the configuration device is further configured to:
receive the user input for at least one of the properties as a SCPI command;
parse the received SCPI command; and
set the at least one of the properties according to the parsed SCPI command.
